(19) United States
(12) Patent Application Publication
(10) Pub. No.: US 2012/0180978 A1
(43) Pub. Date: Jul. 19, 2012

(54) HEAT EXCHANGE DEVICE WITH CONFINED CONVECTIVE BOILING AND IMPROVED EFFICIENCY

(75) Inventors: Jerome Gavillet, Saint-Egreve (FR); Hai Trieu Phan, Grenoble (FR)

(73) Assignee: Commissariat a l'energie atomique et aux ene. alt., Paris (FR)

(21) Appl. No.: 13/395,662

(22) PCT Filed: Sep. 13, 2010
(86) PCT No.: PCT/EP2010/063338

§ 371 Date: Mar. 13, 2012

(30) Foreign Application Priority Data
Sep. 14, 2009 (FR) 0956309

(51) Int. Cl. F28D 15/00; H05K 13/00; F28F 27/00

(52) U.S. Cl. 165/11.1; 165/104.23; 216/13

(57) ABSTRACT

A heat exchange device with convective and confined boiling includes a channel in a substrate in contact with an element to be cooled, in which a polar fluid flows from upstream to downstream, a mechanism of movement of the fluid by convection in the channel imposing a direction of flow, and a device for movement by electro-wetting positioned between the channel and the element to be cooled to move the fluid in the channel. The channel includes an inner surface having low wettability with regard to the polar fluid. The mechanism of movement by electro-wetting includes electrodes and a controller to apply selectively a potential to the electrodes such that an electrostatic force gradient is applied to the fluid in the direction of flow.

### TECHNICAL FIELD AND PRIOR ART

The present invention relates to a heat exchange device with convective and confined boiling and improved efficiency, which can be used for cooling electronic components and components dissipating heat energy.

The phenomenon of boiling is very often used in heat exchange devices; one of the types of boiling conditions used is convective and confined boiling: in these conditions the liquid flows in a pipe of hydraulic diameter less than the capillary length of said liquid.

The bubbles are generally formed upstream, in the channel's first hot zones, above a critical temperature threshold. Subsequently, through a confinement effect, they are crushed and coalesce to form vapour locks. The heat is then principally transmitted through a micro-layer of liquid which is in contact with the wall of the channel. When heat transfer occurs in confined spaces a premature drying of the walls of the channel is generally observed. This drying causes a substantial reduction of the heat exchange coefficient, and therefore reduced efficiency of the element to be cooled.

It is, consequently, one aim of the present invention to provide a diphasic heat exchange device operating in convective and confined boiling conditions, with improved efficiency.

### DESCRIPTION OF THE INVENTION

The previously stated aim is attained through a heat exchange surface in which an electro-wetting device is used to move the drying line in the direction of flow of the liquid, which is formed on the heat exchange surface; thus, by moving this drying line in the liquid's direction of flow the liquid is moved along the wall of the duct, encouraging vapour evacuation.

Indeed, in convective boiling conditions in a micro-channel the liquid is moved in the micro-channel by convection, for example by means of a pump. At the entrance of the channel the liquid is “cold” and the liquid phase is the predominant phase.

Vapour bubbles are formed on the surface of the micro-channel. These increase in number. They coalesce until they fill the centre of the micro-channel. Only a film of liquid remains on the wall of the channel. Vapour is then the predominant phase. And cooling takes place by dissipation of the vapour formed in this manner, which is accomplished in a forced fashion by means of the pump.

By means of the invention, cooling is improved by improving vapour dissipation. To accomplish this, action is taken on the liquid film located on the wall, which is moving at a much lower speed than the centre of the channel, or is even immobile. The film is moved by moving the drying line downstream, and more specifically the liquid front upstream from the drying line, by electro-wetting.

In other words, vapour dissipation is improved by imparting movement to the annular liquid film, this movement assisting the convection of the pump, which improves movement of the vapour downstream of the duct.

The subject-matter of the present invention is then mainly a heat exchange device with convective and confined boiling comprising at least one channel in the substrate intended to be at least partially in contact with an element to be cooled, in which a fluid, the polar component of its surface energy of which is non-zero, is intended to flow from an upstream end to a downstream end, means of movement of the fluid by convection in the channel imposing a direction of flow, a device for movement by electro-wetting located between the channel and the element to be cooled, in order to move the fluid in the channel, where the channel comprises an inner surface having at least partially low wettability with regard to the polar fluid, where said means of movement by electro-wetting comprises a series of electrodes extending between the upstream end and the downstream end, and control means in order to apply a potential selectively to the electrodes, where said control means apply potentials to the electrodes such that an electrostatic force gradient is applied to said fluid in the direction of flow.

In one embodiment the series of electrodes consists of a series of groups of n electrodes which are separately controlled, where n is equal to or greater than 3, and where said electrodes take the form of lines intersecting a direction of flow of the channel.

The series of electrodes can be formed by n parallel tracks, such that the electrodes comprise track portions which are roughly parallel intersecting the liquid's direction of flow, where the control means activate the n tracks in succession.

The n tracks are, for example, between 0.1 mm and 1 mm wide and the distance between them is between 5 μm and 50 μm.

The control means advantageously activate the n tracks periodically with a phase shift of 2π/n and a frequency of between 0.1 Hz and 20 Hz.

n is, for example, equal to 3.

The electrodes can form an angle γ with a direction orthogonal to the direction of flow, where γ is such that 0°≦γ<45°.

The n electrodes can be distributed in several planes.

The electrodes take the form of combs, for example, the fingers of which intersecting the direction of flow are interdigitated.

The control means can periodically apply phase-shifted control signals of square, rectangular, triangular, sinusoidal or other shapes.

The subject-matter of the present invention is also the use of the device according to the present invention to extract heat from an element to be cooled, where said device is in contact with said element to be cooled, or manufactured inside it.

A voltage signal is advantageously applied in succession to the n electrodes to generate a triple-line electrostatic force gradient, assisting the movement of the vapour in the liquid's direction of flow.

The activation frequency of the electrodes can be between 0.1 Hz and 20 Hz.

The subject-matter of of the present invention is also a method for the production of a heat exchange device with convective and confined boiling according to the present invention comprising the following steps:

a) deposition of a first electrical insulating layer on a substrate;

b) deposition of at least one electrical conducting layer on said electrical insulating layer to form electrodes,

c) structuring of said at least one electrical conducting layer to form the electrodes, for example by etching of the electrical conducting layer,

d) deposition of a second electrical insulating layer on the electrical conducting layer,

e) deposition on the second electrical insulating layer of a film having low wettability properties.

Steps b) and c) can be repeated several times such that electrodes are in different planes.

Advantageously, the method of production of a heat exchange device according to the present invention comprises the step of structuring of the insulating layer. Structuring may be obtained by lithography by nano-beads.

For example, the substrate is made from steel, and the first electrical insulating layer is made from SiC/SiO₂. The layer of low wettability is made for example from SiOC.

### BRIEF DESCRIPTION OF THE ILLUSTRATIONS

The present invention will be better understood using the description which follows and the illustrations, in which:

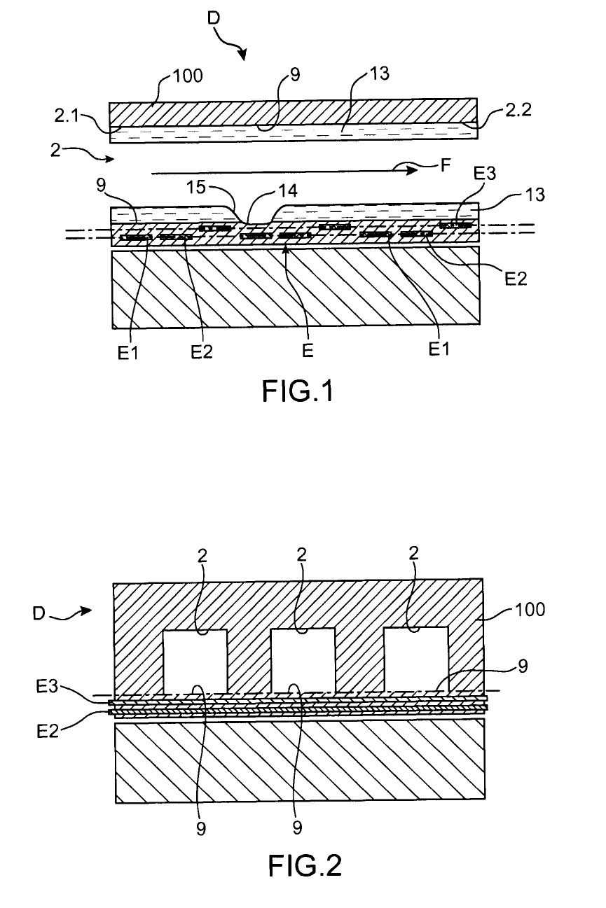

FIG. 1 is a schematic lengthways section view of an example embodiment of a heat exchange device by convective and confined boiling according to the present invention,

FIG. 2 is a transverse section view of the device of FIG. 1, where the latter comprises, in the represented example, three parallel channels,

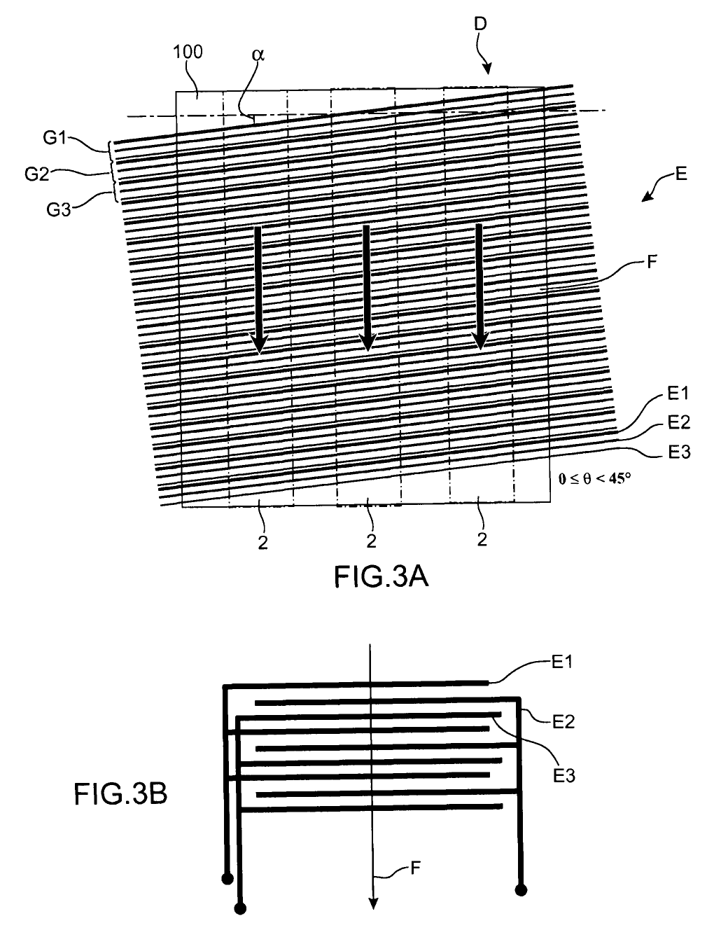

FIG. 3A is a top view of the device of FIG. 1,

FIG. 3B is a detailed view of FIG. 3A,

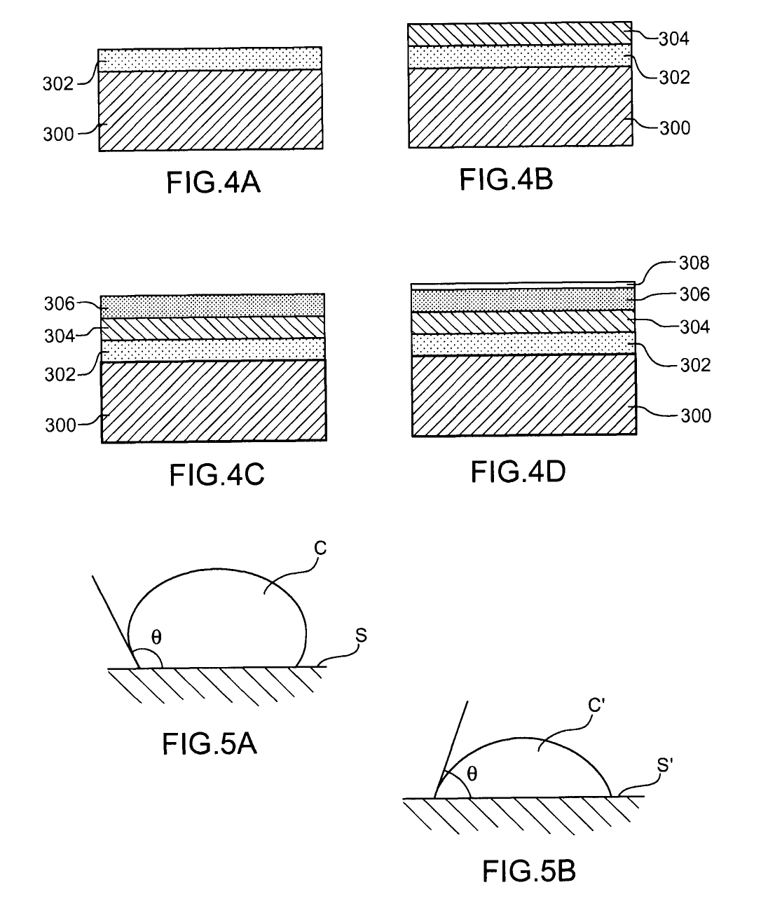

FIGS. 4A to 4D are schematic representations of the different steps of an example of a method of production of a heat exchange device according to the present invention,

FIGS. 5A and 5B are explanatory diagrams of a low-wetting and wetting surface,

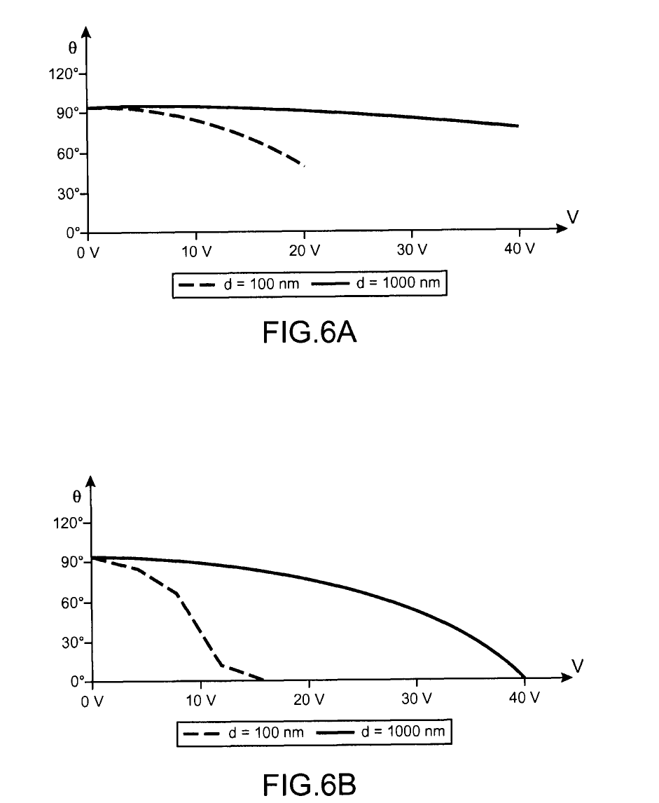

FIGS. 6A and 6B are graphical representations of the change of wettability of two surfaces according to the applied voltage;

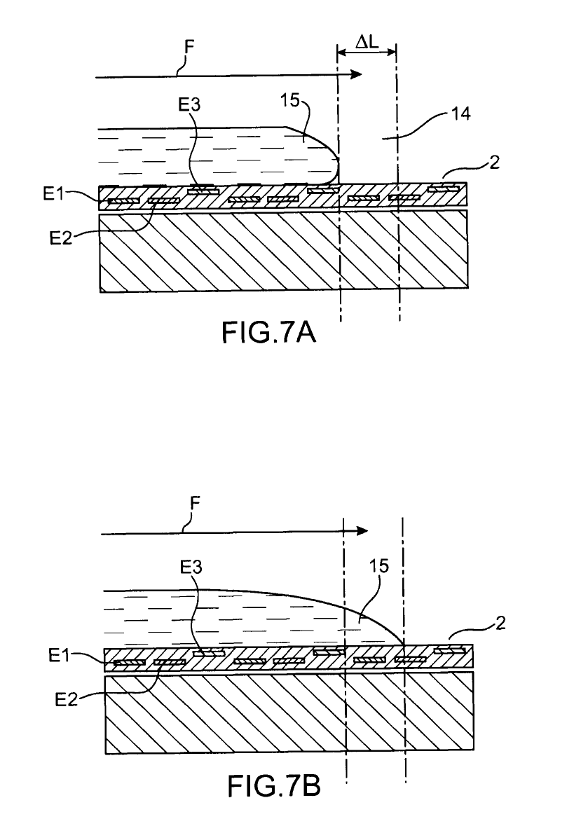

FIGS. 7A and 7B represent respectively the profile of the drying line in a device of the state of the art and in the device according to the present invention.

### DETAILED ACCOUNT OF PARTICULAR EMBODIMENTS

In FIGS. 1 and 2 an example embodiment of a heat exchange device by convective and confined boiling D according to the present invention can be seen, comprising a channel 2 made in a substrate 100, running the length of a thermal element to be cooled T. In the represented example the channel runs the length of element to be cooled T. However, channel 2 could run inside element to be cooled T.

Channel 2 forms part of a circuit comprising means (unrepresented) to cause the liquid to flow, by convection, in the circuit, for example a pump. Channel 2 comprises an upstream end 2.1 through which the fluid enters, and a downstream end 2.2 through which the fluid is evacuated. In the represented example device D comprises three parallel channels 2.

The direction of flow of the fluid by convection is symbolised by arrow F.

A fluid 4, of which the polar component of its surface energy of which is non-zero, designated below the polar fluid, is intended to flow in the circuit in direction F, and in particular in channel 2, before being vaporised in contact with the zone of the channel in contact with element to be cooled T.

According to the present invention, device D comprises a device for movement by electro-wetting 8 positioned, in the represented example, in the internal wall of channel 2 to be cooled T in contact with channel 2.

Device for movement by electro-wetting 8 comprises an electrode path E along channel 2. The electrodes take the form of lines perpendicular to the liquid's direction of flow. In the represented example the same electrodes form the three means of movement by electro-wetting in the three channels, but this is under no circumstances restrictive.

The electrodes are insulated from the polar liquid by an electrical insulating layer (not referenced). In addition, at least the portion of inner surface 9 of channel 2 on the side of element T has properties of low wettability with regard to the liquid phase of the polar fluid.

A surface S has properties of low wettability with regard to a liquid, when contact angle θ of a drop G of said liquid is greater than 90°, as represented in FIG. 5A.

A surface S′ has properties of satisfactory wettability with regard to a liquid, when contact angle θ of a drop G of said liquid is less than 90°, as represented in FIG. 5B.

In FIG. 6B, the changes of the wettability with regard to ethylene glycol of an insulating layer of dielectric constant equal to 8 covered with a hydrophobic film can be seen. The ethylene glycol forms an angle of contact equal to 95° on this hydrophobic film.

The change of contact angle θ according to the voltage applied to the electrode is represented for an insulating layer thickness of 100 nm and an insulating layer thickness of 1000 nm.

It can be seen that, compared to an insulating layer of dielectric constant equal to 2 (represented in FIG. 6A), contact angle θ is reduced more rapidly, and is zero for an insulating layer of 100 nm when the voltage is higher than 15 V, for an insulating layer of thickness 1000 nm when the voltage is equal to or greater than 40 V.

In the case of water, the term hydrophobic surface is used for a low-wetting surface, and the term hydrophilic for a wetting surface. For the sake of simplicity water will be considered to be a fluid with a non-zero polar component in the remainder of the description. But this is in no circumstances restrictive, and the fluid may be, for example, ethylene glycol.

The portion of the inner surface 9 of channel 2 on the side of element T is therefore hydrophobic when no electrical potential is applied.

Control means can apply a potential to one or more electrodes E simultaneously. For example, the control means comprise a switching circuit, closure of which makes a contact between a determined electrode and a voltage source. The switching circuit is programmed to activate the electrodes in succession and over a given time.

In FIGS. 3A and 3B an example embodiment of the device for movement by electro-wetting 8 can be seen, from above.

In this example, device for displacement by electro-wetting 8 comprises a series of groups G1, G2, G3, etc. of three electrodes E1, E2, E3, where each is intended to be activated independently.

The three electrodes E1, E2, E3 enable an electrostatic force gradient to be generated in direction of flow F.

In the represented example, groups G1, G2, G3, etc. of three electrodes E1, E2, E3 are formed from three adjacent parallel conducting tracks. In FIG. 3A a top view of the device can be seen; in this example electrodes E1, E2, E3 are inclined relative to the direction of flow. Electrodes E1, E2, E3 general form with a direction perpendicular to the direction of flow an angle γ greater than or equal to 0°, and in all cases less than 45°.

In FIG. 3B an example embodiment of electrodes E1, E2, E3 in the form of a comb can be seen. The teeth of the three combs intersecting the direction of flow are interdigitated. This configuration enables the connections of the electrodes to the control means to be simplified, since three connections need merely be made between the three combs and the control means.

In the represented example embodiment, electrodes E1 and E2 are in the same plane, whereas electrode E3 is in a higher parallel plane (FIGS. 1 and 2). This configuration is under no circumstances restrictive. The three electrodes can of course be positioned in the same plane, or in three separate parallel planes.

Groups of more than three electrodes could be produced, for example four or five, the advantage of which would be to improve the discretisation of the electrostatic force gradient and to generate, for example, a non-linear gradient.

The path of electrode E is then formed, in this particular example, from lines of parallel electrodes perpendicular to the direction of flow.

As a variant, there could be separate electrodes connected individually to the control means.

In the remainder of the description the term “activation of an electrode” will be used for the application of a potential to an electrode.

The control means apply in succession to each of the tracks of electrodes E1, E2, E3 an activation potential to cause localised application of an electrostatic force on the liquid in channel 2.

For example, the control signals of the three electrodes can be phase-shifted by 2π/3 and can be periodic. The control can be a square, triangular, sinusoidal or other signal. In addition, the periods of activation of the electrodes are not necessarily identical.

We shall now explain the operation of this heat exchange device.

At entrance 2.1 of canal 2 the liquid phase is predominant. In contact with the channel nuclei of vapour bubbles appear, subsequently forming bubbles which become detached. These bubbles are carried away by the flow by convection of the fluid. The bubbles increase in number the further one moves forward in channel 2. The bubbles coalesce, forming a large volume of vapour 11 within the liquid phase.

At a certain time the vapour phase volume is predominant and the liquid phase takes the form of a film 13 on the inner surface of channel 2, separating the channel from the vapour phase. However, this film 13 is not continuous, and in certain locations on part 9 of the inner surface of channel 2 drying lines 14 appear where the liquid film is interrupted. This drying line 14 is lined upstream and downstream by liquid film 13.

The end of the film upstream 15 from drying line 14 will be called the liquid front in the remainder of this document. The zone between the drying line and the liquid front is a triple line. The liquid front is comparable to a drop of liquid, the surface energy polar component of which is non-zero, and which can be moved by electro-wetting.

The control means apply periodic phase-shifted signals to electrodes E1, E2, E3.

For example, electrode E1 is activated for a time t1, and subsequently electrode E2 is activated for a time t2, and subsequently electrode E3 is activated for a time t3. Times t1, t2 and t3 may or may not be equal.

Liquid front 15 is then subject to an electrostatic force gradient generated by the activation of electrodes E1, E2, E3. Due to the hydrophobic character of part 9 of the inner surface of the channel, liquid front 15 has a contact angle greater than 90°.

For an explanation of the operation, it is supposed that liquid front 15 is positioned above an electrode line of electrode E1 (FIG. 1).

Electrode E1 is therefore located close to liquid front 15. When electrode E1 is activated, using control means, the dielectric layer and the hydrophobic layer between this activated electrode and part 9 of the surface under tension act as a condensator.

The counter electrode function is provided by the other unactivated electrodes.

Adjacent electrode E2 is then activated, while electrode E1 is no longer activated, and liquid front 15 is then drawn towards electrode E2.

Electrode E3 is then activated, while electrode E2 is no longer activated, and liquid front 15 is then drawn towards electrode E3.

Liquid front 15 can thus be moved little by little, over the surface, by successive activation of electrodes E1, E2, E3 along the channel. The movement of liquid front 15 generates assists the movement of the vapour downstream of the duct, in a viscous layer which is not affected by the convective forces.

The electrodes are activated in the fluid's direction of flow, i.e. towards the downstream end 2.2 of channel 2, imparting movement to liquid film 15. This movement can be compared to the propagation of a surface wave, where this propagation improves the evacuation of the vapour to the downstream end of the channel.

The three electrode tracks are roughly parallel, such that the drying line meets these three tracks in succession. Thus, the phase-shifted variation of the contact angle above these three adjacent tracks will enable liquid front 15 to be moved in the direction of flow.

This configuration of electrodes enables the connection between the control means and the electrodes to be simplified, since three connections are all that is required to control the entire electrode path. In addition, the entire length of the duct is swept more rapidly, since the potential is applied simultaneously to all the portions of electrodes belonging to the activated track.

It should be noted that the position of the liquid front is statistical; consequently it is therefore preferable for the electrostatic surface wave to cover the entire length of the channel.

As an example, the electrical potentials of the conducting tracks the electrical potentials of which vary periodically are phase-shifted by 2π/3 relative to one another with a frequency of between 0.1 Hz and 20 Hz. Such a frequency corresponds to a sufficient period during which liquid front 15 is moved through a distance equivalent to at least three successive electrodes. The speed of liquid front 15 is estimated at approximately 1 mm/s to 80 mm/s and the distance covered by the three electrodes is approximately 3 mm.

For example, the tracks are between 0.1 mm and 1 mm wide, and are separated by a distance of between 5 μm and 50 μm. The diameter of the channel may vary between 0.1 mm and 2 mm.

It is clearly understood that every other type of configuration for the device for movement by electro-wetting allowing movement in a given direction of the liquid front may be suitable.

If each electrode is controlled individually operation is similar to that of the device of 1 an 2; in this case, however, only a single electrode is activated at once.

We shall now compare the shape of the triple line in a heat exchange device with convective boiling of the state of the art, and that in the device according to the invention.

In FIG. 7A the profile of the triple line in a known device can be seen; the triple line's movement is due only to the means of movement by convection.

In convective boiling the liquid is vaporised due to the flow of heat originating from the part to be cooled T. When the drying takes place, in the contact triple line, heat transfer is high and can by this means create a greater evaporation flow than in the wet zone. The curvature of the liquid-vapour interface is thus changed and leads to the appearance of a contact angle which is called a “micro-contact angle” a, of over 90°. Thus, the horizontal component of the surface tension force F_{σ} creates a widening of the dried zone over a distance ΔL.

In FIG. 7B the profile of the triple line in the device according to the present invention can be seen. By applying a surface wave the triple contact line is moved in the direction of flow, thus preventing the appearance of the micro-contact angle. The horizontal component of the surface tension force F_{σ} does not create a widening of the dried zone. The dried zone is then reduced by a distance ΔL.

We shall now describe a method of production of such heat exchange devices.

A substrate 100 is used, made for example of a metal such as, for example, aluminium or copper, or of a metal alloy, or silicon dioxide.

The substrate is advantageously made from steel.

During a first step represented in FIG. 4A an electrically insulating layer 102 is deposited on the substrate; the purpose of this layer is to provide an electrical insulation between the substrate and the metal layer used for the production of the electrodes.

For example, the electrical insulating layer consists of SiC, SiN, SiO₂ or a combination of these materials. Advantageously, layer 102 is made from SiC/SiO₂, providing satisfactory adhesion to the substrate, firstly, and to the conducting layer which will form the electrodes, secondly.

The thickness of layer 102 is chosen such that it is sufficiently low that it does not substantially affect the heat exchange between the element to be cooled and the fluid. For example, the thickness of SiC/SiO₂ is of the order of 100 nm to 1000 nm for an apparent dielectric constant ε of the order of 2-8.

This layer can be deposited by a conventional vacuum deposition method of the PVD type (physical deposition in the vapour phase) or CVD type (chemical deposition in the vapour phase).

During a following step represented in FIG. 4B, an electrically conducting layer 104 is deposited on the electrically insulating layer 102 in the form of a thin film. Conducting layer 104 is made, for example, of copper, gold, titanium, molybdenum or another conducting material or alloy. It is between 100 nm and 1000 nm thick, for example. This layer can be deposited by a conventional vacuum deposition method of the PVD type.

In a following step (not represented) the electrodes are structured. This structuring can be accomplished, for example, by means of a physical mask deposited on layer 104. The visible portion of layer 104 is then etched and the mask removed. It is also possible to accomplish this structuring by a lift-off method, i.e. the mask made from photosensitive resin is deposited before depositing conducting layer 104, where the mask is a negative of the structure desired for the electrodes. Conducting layer 104 is then deposited on the mask. The mask is then eliminated, for example by means of a solvent, removing the zones of layer 104 deposited on the mask.

These last three steps of deposition of layer 102, of deposition of layer 104 and then of electrode structuring of layer 104 are repeated in identical fashion. Thus, lower layer 104 could, for example, support electrodes E1 and E2, while upper layer 104 could, for example, support layer E3 (FIG. 2).

During a following step represented in FIG. 4C, a second electrically insulating layer 106 is deposited on the electrodes.

It is similar to the first layer 102. It can be made from the same material or a different material.

It is, for example, between 100 nm and 1000 nm thick for an apparent dielectric constant ε of the order of 2-8.

In a following step represented in FIG. 4D, a hydrophobic layer 108 is deposited which will be in contact with the fluid. This layer is made, for example, of SiOC. It is between 10 nm and 100 nm thick, for example. It is deposited by a conventional vacuum deposition method of the PECVD type.

The surface energy of this layer, and more specifically its polar component, is modified under the effect of an electric field imposed by the electrodes formed in lower and upper conducting layer 104, which enables its water-wetting property to be switched from the hydrophobic domain to the hydrophilic domain. Layer 106 as described above enables, with a low voltage in metal layer 104 of below 40 V, an electric field to be generated at the surface sufficient to modify the surface energy of hydrophobic layer 108.

Advantageously, it is possible to accomplish a structuring at the surface of the second insulating layer 106 prior to the deposition of hydrophobic layer 108 in order to accentuate the hydrophilic and hydrophobic properties, to attain super-hydrophilicity and super-hydrophobicity properties.

The effect of this structuring is to increase the electro-wetting dynamics.

In the case of a structuring of layer 106, the thickness of this layer can be increased from 0 nm to 1000 nm. Alternatively, an additional layer of another insulating material can be deposited on layer 106. For example, a layer of carbon in the form of carbon-like-diamond (DLC) 50 nm to 1000 nm thick. The pattern is then printed in this added thickness of layer 106 or in the new layer by, for example, lithography by nano-beads of diameter of the order of 500 nm to 1000 nm. In this case, a single layer of silicon dioxide beads can be deposited by a Langmuir-Blodgett method, and plasma etching through this mask of beads can be accomplished in overlayer 106 or in the additional layer. This step of etching leads the pattern to be opened as far as the upper interface of layer 106. The beads can then be removed simply by ultrasound.

The present invention applies notably to the production of diphasic heat exchangers, diphasic thermosiphons and heat pipes.

1-19. (canceled)

20. A heat exchange device with convective and confined boiling, comprising:
at least one channel in the substrate configured to be at least partially in contact with an element to be cooled, in which a polar fluid, the polar component of its surface energy of which is non-zero, can flow from an upstream end to a downstream end, an inner surface having at least partially low wettability with regard to the polar fluid;
a device of movement of the fluid by convection in the channel imposing a direction of flow; and
a device for movement by electro-wetting located between the channel and the element to be cooled, to move the fluid in the channel, the device of movement by electro-wetting comprising a series of electrodes extending between the upstream end and the downstream end, and a controller to apply a potential selectively to the electrodes, the controller applying potentials to the electrodes such that an electrostatic force gradient is applied to the polar fluid in the direction of flow.

21. A heat exchange device with convective and confined boiling according to claim 20, in which the series of electrodes includes a series of groups of n separately controlled electrodes, wherein n is equal to or greater than 3, and in which the electrodes take a form of lines intersecting a direction of flow of the channel.

22. A heat exchange device with convective and confined boiling according to claim 20, in which the series of electrodes is formed by n parallel tracks such that the electrodes comprise roughly parallel portions of track intersecting the fluid's direction of flow, wherein the controller activates the n tracks in succession.

23. A heat exchange device with convective and confined boiling according to claim 21, in which the n tracks are between 0.1 mm and 1 mm wide and the distance between them is between 5 μm and 50 μm.

24. A heat exchange device with convective and confined boiling according to claim 21, in which the controller activates the n tracks periodically with a phase shift of 2π/n and a frequency of between 0.1 Hz and 20 Hz.

25. A heat exchange device with convective and confined boiling according to claim 21, in which n is equal to 3.

26. A heat exchange device with convective and confined boiling according to claim 21, in which the electrodes form an angle γ with a direction orthogonal to the direction of flow, where γ is such that 0°≦γ<45°.

27. A heat exchange device with convective and confined boiling according to claim 21, in which the n electrodes are distributed in plural planes.

28. A heat exchange device with convective and confined boiling according to claim 21, in which the electrodes take a form of combs, fingers of which, intersecting the direction of flow, are interdigitated.

29. A heat exchange device with convective and confined boiling according to claim 20, in which the controller applies phase-shifted control signals periodically of a square, rectangular, triangular, sinusoidal or other shape.

30. A heat exchange device with convective and confined boiling according to claim 22, in which the n tracks are between 0.1 mm and 1 mm wide and the distance between them is between 5 μm and 50 μm.

31. A heat exchange device with convective and confined boiling according to claim 22, in which the controller activates the n tracks periodically with a phase shift of 2π/n and a frequency of between 0.1 Hz and 20 Hz.

32. A heat exchange device with convective and confined boiling according to claim 22, in which n is equal to 3.

33. A heat exchange device with convective and confined boiling according to claim 22, in which the electrodes form an angle γ with a direction orthogonal to the direction of flow, where γ is such that 0°≦γ<45°.

34. A heat exchange device with convective and confined boiling according to claim 22, in which the n electrodes are distributed in plural planes.

35. A heat exchange device with convective and confined boiling according to claim 22, in which the electrodes take a form of combs, fingers of which, intersecting the direction of flow, are interdigitated.

36. A heat exchange device with convective and confined boiling according to claim 22, in which the controller applies phase-shifted control signals periodically of a square, rectangular, triangular, sinusoidal, or other shape.

37. Use of a heat exchange device with convective and confined boiling to extract heat from an element to be cooled, wherein the device is in contact with the element to be cooled, or manufactured inside it, the heat exchange device comprising:
at least one channel in the substrate configured to be at least partially in contact with an element to be cooled, in which a polar fluid, the polar component of its surface energy of which is non-zero, can flow from an upstream end to a downstream end, an inner surface having at least partially low wettability with regard to the polar fluid;
a device of movement of the fluid by convection in the channel imposing a direction of flow; and
a device for movement by electro-wetting located between the channel and the element to be cooled, to move the fluid in the channel, the device of movement by electro-wetting comprising a series of electrodes extending between the upstream end and the downstream end, and a controller to apply a potential selectively to the electrodes, the controller applying potentials to the electrodes such that an electrostatic force gradient is applied to the fluid in the direction of flow

38. Use according to claim 37, in which a voltage signal is applied in succession to the n electrodes to generate a triple-line electrostatic force gradient, assisting movement of vapor in the liquid's direction of flow.

39. Use according to claim 38, in which frequency of activation of the electrodes is between 0.1 Hz and 20 Hz.

40. A method of production of a heat exchange device with convective and confined boiling, the device comprising:
at least one channel in the substrate configured to be at least partially in contact with an element to be cooled, in which a polar fluid, the polar component of its surface energy of which is non-zero, can flow from an upstream end to a downstream end, an inner surface having at least partially low wettability with regard to the polar fluid;
a device of movement of the fluid by convection in the channel imposing a direction of flow; and
a device for movement by electro-wetting located between the channel and the element to be cooled, to move the fluid in the channel, the device of movement by electro-wetting comprising a series of electrodes extending between the upstream end and the downstream end, and a controller to apply a potential selectively to the electrodes, the controller applying potentials to the electrodes such that an electrostatic force gradient is applied to the fluid in the direction of flow, the method comprising:
a) deposition of a first electrical insulating layer on a substrate;
b) deposition of at least one electrical conducting layer on the electrical insulating layer to form electrodes;
c) structuring of the at least one electrical conducting layer to form the electrodes, or by etching of the electrical conducting layer;
d) deposition of a second electrical insulating layer on the electrical conducting layer;
e) deposition on the second electrical insulating layer of a film having low wettability properties.

41. A method of production of a heat exchange device with convective and confined boiling according to claim 40, in which b) and c) are repeated plural times such that electrodes are in different planes.

42. A method of production of a heat exchange device according to claim 40, further comprising f) structuring the insulating layer.

43. A method of production of a heat exchange device according to claim 42, wherein the structuring is obtained by lithography by nano-beads.

44. A method of production of a heat exchange device according to claim 40, in which the substrate is made of steel, and the first electrically insulating layer is made of SiC/SiO₂.

45. A method of production of a heat exchange device according to claim 40, in which the layer of low wettability is made of SiOC.
